(19) United States
(12) Patent Application Publication
(10) Pub. No.: US 2022/0195588 A1
(43) Pub. Date: Jun. 23, 2022

(54) PROCESS FOR APPLYING A PHYSICAL VAPOR DEPOSITION TO A SINK BLANK

(71) Applicant: MILA INTERNATIONAL INC., Huntington Beach, CA (US)

(72) Inventor: Shujen YU, Huntington Beach, CA (US)

(21) Appl. No.: 17/600,933

(22) PCT Filed: Apr. 2, 2019
(86) PCT No.: PCT/US2019/025409

§ 371 Date: Oct. 1, 2021

(51) Int. Cl. C23C 14/56; C23C 14/02; C23C 14/58

(52) U.S. Cl. CPC C23C 14/56; C23C 14/5886; C23C 14/021

(57) ABSTRACT

In an example, a method for forming a sink is disclosed. The method includes positioning a blank in a vacuum chamber. The blank is formed from a metal sheet. The method also includes applying a physical vapor deposition (PVD) process to the blank within the vacuum chamber to form a hardcoat layer over a surface of the blank and manipulating the blank to form the sink.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a process for applying a physical vapor deposition (PVD) process to a sink blank.

Sinks made from stainless steel provide excellent durability in comparison to some other materials. Stainless steel sinks can be used in harsh environments to resist damage. Additionally, stainless steel sinks can be used to compliment certain kitchen designs.

### SUMMARY

In an example, a method for forming a sink is disclosed. The method includes positioning a blank in a vacuum chamber. The blank is formed from a metal sheet. The method also includes applying a physical vapor deposition (PVD) process to the blank within the vacuum chamber to form a hardcoat layer over a surface of the blank and manipulating the blank to form the sink.

In other features, the method includes receiving the metal sheet.

In other features, the method includes cutting the metal sheet to form the blank.

In other features, the method includes cleaning the blank prior to positioning the blank in the vacuum chamber.

In other features, the method includes pressing the blank to form the sink via a pressing machine.

In other features, the method includes pressing the blank to form a basin portion and a flange portion.

In other features, the blank comprises stainless steel.

In other features, the method includes scoring a portion of the blank along an axis corresponding to a bend line of the sink.

In an example, a method for forming a sink is disclosed. The method includes positioning a stainless steel blank in a vacuum chamber, applying a physical vapor deposition (PVD) process to the stainless steel blank within the vacuum chamber to form a hardcoat layer over a surface of the stainless steel blank, after applying the PVD process, scoring the stainless steel blank along an axis corresponding to a bend line, and manipulating the stainless steel blank to form the sink.

In other features, the method includes receiving a stainless steel metal sheet.

In other features, the method includes cutting the stainless steel metal sheet to form the stainless steel blank.

In other features, the method includes cleaning the stainless steel blank prior to positioning the blank in the vacuum chamber.

In other features, the method includes pressing the stainless steel blank to form the sink via a pressing machine.

In other features, the method includes pressing the stainless steel blank to form a basin portion and a flange portion.

In an example, a method for forming a sink is disclosed. The method includes positioning the stainless steel blank in a vacuum chamber, applying a physical vapor deposition (PVD) process to the stainless steel blank within the vacuum chamber to form a hardcoat layer over a surface of the stainless steel blank, after applying the PVD process, scoring the stainless steel blank along an axis corresponding to a bend line, and manipulating the stainless steel blank to form the sink.

In other features, the method includes receiving the stainless steel blank.

In other features, the method includes cleaning the stainless steel blank prior to positioning the stainless steel blank in the vacuum chamber.

In other features, the method includes pressing the stainless steel blank to form the sink via a pressing machine.

In other features, the method includes pressing the stainless steel blank to form a basin portion and a flange portion.

In other features, the method includes scoring the stainless steel blank along the axis corresponding to the bend line via a milling machine.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a flow diagram illustrating an example method for applying a physical vapor deposition (PVD) process to a blank prior to pressing the blank to form a sink in accordance with an example implementation of the present disclosure;

FIG. 2 is a plan view of a metal sheet in accordance with an example implementation of the present disclosure;

FIG. 3 is a plan view of a blank formed from the metal sheet shown in FIG. 2 in accordance with an example implementation of the present disclosure;

FIG. 4 is an isometric view illustrating a sink formed by pressing a blank subjected to a PVD process in accordance with an example implementation of the present disclosure.

In the drawings, reference numbers may be reused to identify similar and/or identical elements.

### DETAILED DESCRIPTION

Sinks may be formed from a single sheet of stainless steel. The sheet can be manipulated to form one or more basin portions and one or more flange portions. In some instances, physical vapor deposition (PVD) processes are applied to these sinks after the sinks have been already formed. Using a PVD process, a finish is molecularly bonded to the surface of the sink to create a durable exterior surface. PVD finishes can mitigate corrosion, discoloring, and/or tarnishing.

However, applying the PVD process to a sink that is already formed may result in portions, such as the corners, of the sink not having a uniform exterior surface. The present disclosure is directed to a process of subjecting a sink blank to a PVD process prior to the sink blank being manipulated to form the sink.

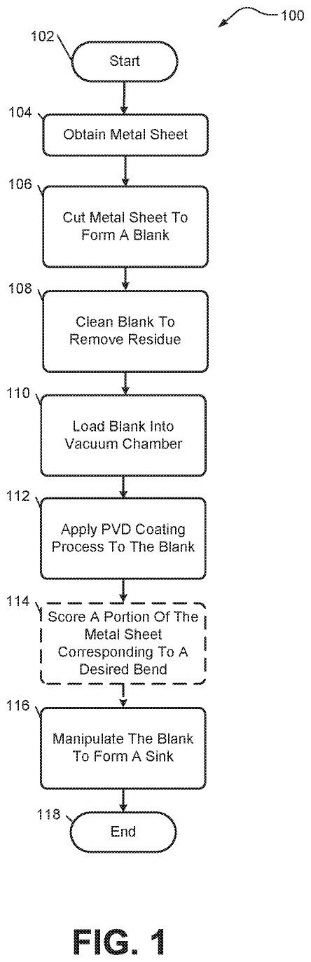

FIG. 1 illustrates a flow diagram of an example method 100 for applying a PVD process to a sink. The method 100 begins at 102. At 104, a metal sheet is obtained. For example, a single flat sheet of stainless steel having a substantially uniform thickness is obtained. At 106, the metal sheet is cut to form a blank. At 108, the blank is cleaned to remove residue. For example, the blank can be cleaned to remove polished compounds, grease, oil, fingerprints, or the like.

At 110, the blank is loaded into a vacuum chamber. Once loaded into the vacuum chamber, a PVD coating process is applied to the blank to form a hardcoat layer over the surfaces of the blank at 112. Suitable PVD processes include, but are not limited to, sputtering, reactive sputtering, evaporation, reactive evaporation, ion-assisted reactive evaporation, ion-beam assisted deposition, cathodic arc evaporation, unbalanced magnetron sputtering, high power impulse magnetron sputtering (HIPIMS), thermal and electron beam (e-beam) evaporation, and the like.

At 114, the blank can be milled to remove portions of the blank that correspond to a desired bend for the sink. In one or more implementations, the blank is received by a milling machine. Once the blank has been received, a cutter of the milling machine removes the portions of the sink that correspond to a bend line of the sink. At 116, the blank is manipulated to form a sink. For example, the blank can be positioned within a machine press that forms one or more bowls within the blank. At 118, the method 100 ends. It is understood that the blank may not be subjected to a milling process prior to positioning the blank within the machine press. For example, the blank may be positioned within the machine press after the blank is subjected to the PVD coating process.

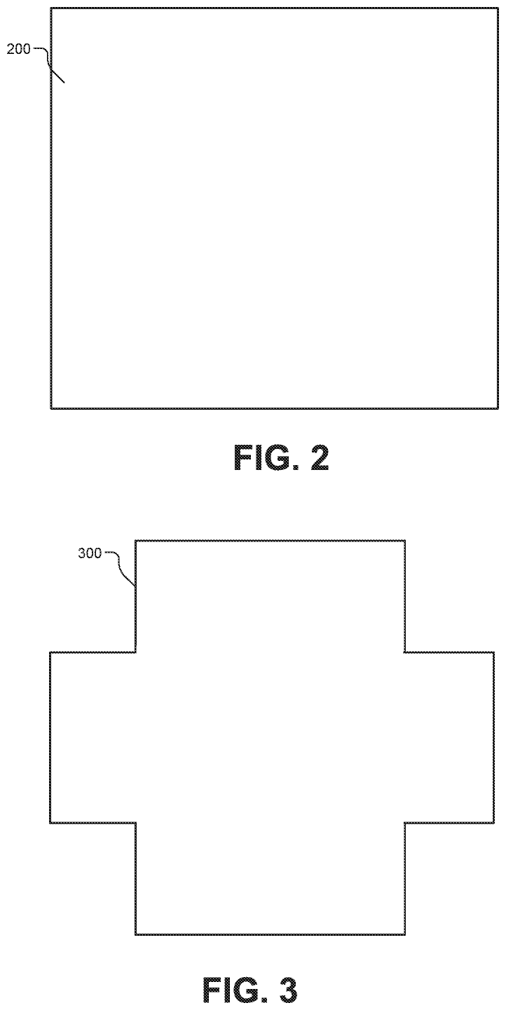

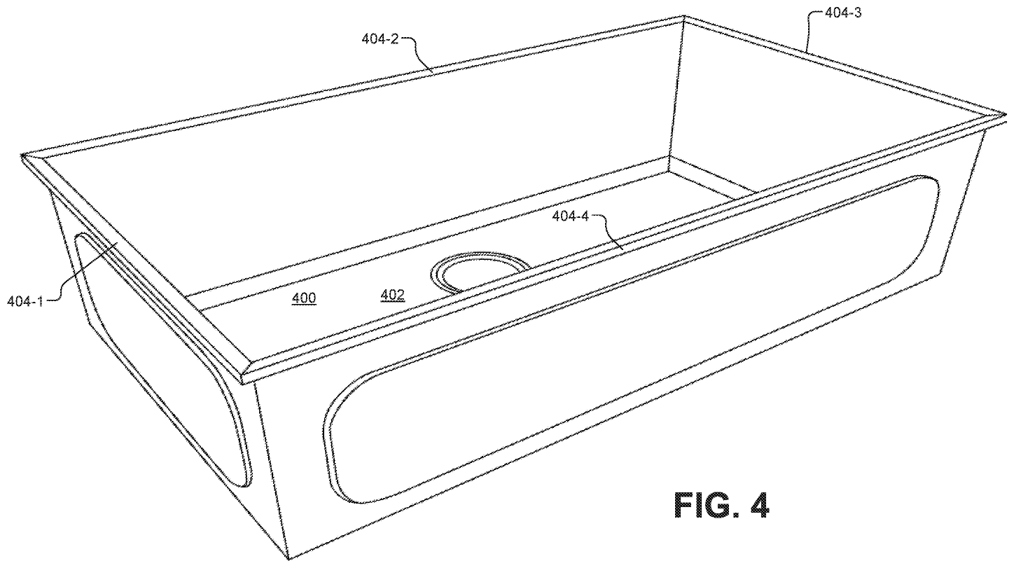

FIG. 2 illustrates an example metal sheet 200. FIG. 3 illustrates an example blank 300 formed from the metal sheet 200. For example, the metal sheet 200 is subjected to one or more cutting processes to form the blank 300. FIG. 4 illustrates an example sink 400 having a basin portion 402 and flange portions 404-1 through 404-4. For example, the blank 300 is inserted into a press. The press applies pressure to the blank 300 to form a sink having at least one basin portion and one or more flange portions. In this example, the blank 300 is subjected to a press to form the sink 400 having the basin portion 402 and the flange portions 404-1 through 404-4.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

None of the elements recited in the claims are intended to be a means-plus-function element within the meaning of 35 U.S.C. §112(f) unless an element is expressly recited using the phrase “means for,” or in the case of a method claim using the phrases “operation for” or “step for.”

What is claimed is:

1. A method for forming a sink comprising:
positioning a blank in a vacuum chamber, wherein the blank is formed from a metal sheet;
applying a physical vapor deposition (PVD) process to the blank within the vacuum chamber to form a hardcoat layer over a surface of the blank; and
manipulating the blank to form the sink.

2. The method as recited in claim 1, further comprising receiving the metal sheet.

3. The method as recited in claim 2, further comprising cutting the metal sheet to form the blank.

4. The method as recited in claim 2, further comprising cleaning the blank prior to positioning the blank in the vacuum chamber.

5. The method as recited in claim 1, wherein manipulating the blank further comprises pressing the blank to form the sink via a pressing machine.

6. The method as recited in claim 5, wherein pressing the blank further comprises pressing the blank to form a basin portion and a flange portion.

7. The method as recited in claim 1, wherein the blank comprises stainless steel.

8. The method as recited in claim 1, further comprising scoring a portion of the blank along an axis corresponding to a bend line of the sink.

9. A method for forming a sink comprising:
positioning a stainless steel blank in a vacuum chamber;
applying a physical vapor deposition (PVD) process to the stainless steel blank within the vacuum chamber to form a hardcoat layer over a surface of the stainless steel blank;
after applying the PVD process, scoring the stainless steel blank along an axis corresponding to a bend line; and
manipulating the stainless steel blank to form the sink.

10. The method as recited in claim 9, further comprising receiving a stainless steel metal sheet.

11. The method as recited in claim 10, further comprising cutting the stainless steel metal sheet to form the stainless steel blank.

12. The method as recited in claim 11, further comprising cleaning the stainless steel blank prior to positioning the blank in the vacuum chamber.

13. The method as recited in claim 9, wherein manipulating the stainless steel blank further comprises pressing the stainless steel blank to form the sink via a pressing machine.

14. The method as recited in claim 13, wherein pressing the stainless steel blank further comprises pressing the stainless steel blank to form a basin portion and a flange portion.

15. A method for forming a sink comprising:
cutting a stainless steel metal sheet to form a stainless steel blank;
positioning the stainless steel blank in a vacuum chamber;
applying a physical vapor deposition (PVD) process to the stainless steel blank within the vacuum chamber to form a hardcoat layer over a surface of the stainless steel blank;
after applying the PVD process, scoring the stainless steel blank along an axis corresponding to a bend line;
manipulating the stainless steel blank to form the sink.

16. The method as recited in claim 15, further comprising receiving the stainless steel blank.

17. The method as recited in claim 15, further comprising cleaning the stainless steel blank prior to positioning the stainless steel blank in the vacuum chamber.

18. The method as recited in claim 15, wherein manipulating the stainless steel blank further comprises pressing the stainless steel blank to form the sink via a pressing machine.

19. The method as recited in claim 18, wherein pressing the stainless steel blank further comprises pressing the stainless steel blank to form a basin portion and a flange portion.

20. The method as recited in claim 15, wherein scoring the stainless steel blank further comprises scoring the stainless steel blank along the axis corresponding to the bend line via a milling machine.
